(19) United States
(12) Patent Application Publication
(10) Pub. No.: US 2019/0330740 A1
(43) Pub. Date: Oct. 31, 2019

(54) SUBSTRATE PROCESSING APPARATUS AND METHOD

(71) Applicant: ASM IP Holding B.V., Almere (NL)

(72) Inventor: Arjen Klaver, Neerijse (BE)

(21) Appl. No.: 15/967,146

(22) Filed: Apr. 30, 2018

(51) Int. Cl. C23C 16/52; C23C 16/455; C23C 16/44

(52) U.S. Cl. CPC C23C 16/52; C23C 16/4401; C23C 16/45502; C23C 16/4557

(57) ABSTRACT

A substrate processing apparatus with a reaction chamber and a substrate holder constructed and arranged to hold at least one substrate in said reaction chamber is provided. A first and second gas injector provides a process gas to the interior of the reaction chamber from a source pipe. A gas control system provides a flow of process gas from the source pipe to the first injector while restricting a flow of the same process gas from the source pipe to the second injector.

### FIELD

The present invention relates to a substrate processing apparatus and method. In particular it relates to a substrate processing apparatus with a reaction chamber and a substrate holder constructed and arranged to hold at least one substrate in said reaction chamber. A gas injector system may provide a process gas to the interior of the reaction chamber from a source pipe under control of a gas control system.

### BACKGROUND

The substrate processing apparatus for processing substrates, such as, for example, semiconductor wafers, may include a heating means, placed around a bell jar-shaped process tube functioning as a reaction chamber. The upper end of the process tube may be closed, for example, by a dome-shaped structure, whereas the lower end surface of the process tube may be open. The lower end may be partially closed by a flange. An interior of the reaction chamber bounded by the tube and the flange forms the reaction chamber in which wafers to be treated may be processed. The flange may be provided with an inlet opening for inserting a wafer boat carrying wafers into the interior. The wafer boat may be placed on a door that is vertically moveably arranged and that is configured to close off the inlet opening in the flange.

The apparatus may further be provided with a gas injector system which is in fluidum connection with the interior of the reaction chamber. The injector system may be provided with an injector with at least one opening in the injector. Through the injector a process gas may be flowed via the at least one opening into the interior to react with the substrate.

A gas exhaust may be provided that is in fluidum connection with the interior. The gas exhaust may be connected to a vacuum pump for pumping off gas from the interior of the reaction chamber. This configuration may lead to a gas flow from the injector through the reaction chamber to the gas exhaust. The gas in the flow may be a reaction (process) gas for a deposition reaction on the substrate. This reaction gas may also deposit on other surfaces than the substrate within the interior of the reaction chamber.

Deposition within an injector of the injector system may cause clogging of the injector or the at least one opening in the injector, which may be detrimental to the working of the injector system. Further deposition in the injector may cause flakes to fall off during heat up and/or cool down of the reaction chamber, which may contaminate the substrate. By replacing the injector with a new clean injector during maintenance of the apparatus, these issues may be alleviated. To replace the injector with a new, clean injector, the reaction chamber must be opened, which may be a cumbersome procedure leading to down time and interrupting production of the apparatus.

### SUMMARY

Accordingly, an improved substrate processing apparatus and method leading to an increased production may be required.

Accordingly, there may be provided a substrate processing apparatus comprising: a reaction chamber and a substrate holder constructed and arranged to hold at least one substrate in said reaction chamber. The apparatus may comprise a gas injector system constructed and arranged to provide a process gas to the interior of the reaction chamber. The gas injector system may be provided with a gas control system constructed and arranged to control the process gas flow from a source pipe. The gas injector system may comprise a first and second injector for providing the same process gas to the reaction chamber. The gas control system may be constructed and/or programmed to provide a flow of the process gas from the source pipe to one of the first and second injectors, while restricting a flow of the same process gas to the other of the first and second injectors.

The production period may be increased by using said one of the first and second injectors while restricting a flow of the process gas through the other of the first and second injectors to keep the other of the first and second injectors initially clean. Deposition within said one injector may cause it to deteriorate and the clean other injector may be used to alleviate that after a while. The flow of the process gas through said one first injector may then be restricted while using the other injector for deposition.

Switching the process gas between the first and the second injectors may lead to longer production cycles since it takes longer for the deposition to build up in the first and second injector compared to the situation where the deposition is building up in only one injector. The gas control system may be constructed and/or programmed to switch the flow of process gas from the first to the second injector when the first injector deteriorates and/or just periodically. Switching between the first and second injector may be done one time or multiple times back and forth.

Only when both the first and second injectors have been deteriorated replacement of the first and second injectors may be necessary and the reaction chamber may be opened. By using two injectors the production period may be extended, leading to increased productivity. It must be understood that the number of injectors in the injector system may be increased to three, four or even five to further increase the production.

According to an embodiment there is provided a substrate processing method comprising:

providing a substrate on a substrate holder in a reaction chamber;

providing a flow of a process gas from a source pipe with a first gas injector into the interior of the reaction chamber; and,

restricting a flow of the same process gas from the source pipe to a second injector into the interior of the reaction chamber.

The substrate processing method has the advantages which has been described above with reference to substrate processing apparatus. An advantage may be that the production period may be increased and the down time may be decreased.

The various embodiments of the invention may be applied separate from each other or may be combined. Embodiments of the invention will be further elucidated in the detailed description, with reference to some examples shown in the figures.

### BRIEF DESCRIPTION OF THE FIGURES

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

FIG. 1 illustrates a cross-sectional view of a substrate processing apparatus according to an embodiment;

FIG. 2a illustrates an additional view of a substrate processing apparatus according to an embodiment;

FIG. 2b illustrates a view on a gas injector system constructed and arranged to provide a process gas to the interior of the reaction chamber of FIG. 1 or 2a;

FIG. 3 depicts a perspective bottom view of an injector according to an embodiment located within the reaction chamber of the apparatus according to FIG. 1 or 2a; and,

FIG. 4 depicts an injector for use in FIG. 1, 2a, 2b or 3.

### DETAILED DESCRIPTION

In this application similar or corresponding features are denoted by similar or corresponding reference signs. The description of the various embodiments is not limited to the examples shown in the figures and the reference numbers used in the detailed description and the claims are not intended to limit what is described in connection with the examples shown in the figures.

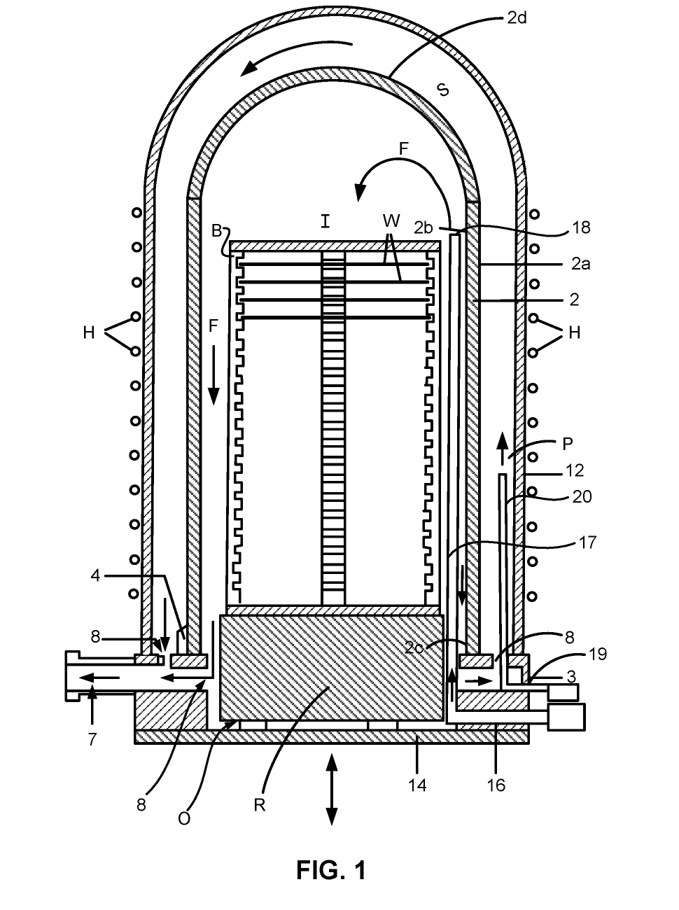

FIG. 1 shows a cross-sectional view of a substrate processing apparatus according to an embodiment. The apparatus may comprise a reaction chamber and a substrate holder constructed and arranged to hold at least one substrate in said reaction chamber.

The reaction chamber may be, for example, the low pressure process tube 12 defining an interior and a heater H configured to heat the interior. A liner 2 may be extending in the interior, the liner comprising a substantially cylindrical wall delimited by a liner opening at a lower end and a dome shape top closure 2d at the higher end. The liner may be substantially closed for gases above the liner opening and defines an inner space I being part of the interior of the tube 12.

A flange 3 may be provided to at least partially close the opening of the low pressure process tube 12. A vertically movably arranged door 14 may be configured to close off a central inlet opening O in the flange 3 and may be configured to support a wafer boat B that is configured to hold substrates W. The flange 3 may be partially closing an open end of the process tube 12. The door 14 may be provided with a pedestal R. The pedestal R may be rotated to have the wafer boat B in the inner space rotating.

In the example shown in FIG. 1, the flange 3 comprises a process gas inlet 16 to provide a process gas F to the inner space I and a gas exhaust duct 7 to remove gas from the inner space. The process gas inlet 16 may be provided with an injector 17 constructed and arranged to extend vertically into the inner space I along the substantial cylindrical wall of the liner 2 towards the higher end and comprising an injector opening 18 to inject gas in the inner space I. Gas exhaust openings 8 connected to the gas exhaust duct 7 for removing gas from the inner space may be constructed and arranged below the injector opening 18. In this way, by closing the liner 2 above the liner opening for gases, providing a gas to the inner space with the injector 17 through the injector opening 18 at an upper end of the inner space I and removing gas from the inner space by the gas exhaust openings 8 at a lower end of the inner space a down flow F in the inner space of the liner 2 may be created. This down flow F may transport contamination of reaction byproducts, particles from the injector 17, the substrate W, the boat B, the liner 2 and/or the support flange 3 downward to the exhaust openings 8 away from the processed substrates W.

The gas exhaust opening 8 for removing gas from the inner space I may be provided below the open end of the liner 2. This may be beneficial since a source of contamination of the process chamber may be formed by the contact between the liner 2 and the flange 3. More specifically the source may exist, at the position where a lower end surface of the liner at the open end is in contact with the flange. The liner 2 may be made from silicon carbide and the flange from metal, the liner and the flange may move with respect to each other during thermal expansion. The friction between the lower end surface of the liner and the upper surface of the flange may result in contaminants, e.g., small particles breaking away from liner and/or flange. The particles may migrate into the process chamber and may contaminate the process chamber and the substrates which are being processed.

By closing the liner above the liner opening for gases, providing a process gas to the inner space with the gas injector at an upper end of the inner space and removing gas from the inner space by the gas exhaust at a lower end of the inner space, a down flow in the inner space may be created. This down flow may transport the particles from the liner-flange interface downward to the exhaust away from the processed substrates.

The gas exhaust openings 8 may be constructed and arranged in the flange 3 between the liner 2 and the tube 12 for removing gas from the circumferential space between the liner 2 and the tube 12. In this way, the pressure in the circumferential space and the interior space I may be made equal and in a low pressure vertical furnace may be made lower than the surrounding atmospheric pressure surrounding the tube 12. The vertical furnace may be provided with a pressure control system to remove gas from the interior of the tube (including the inner space of the liner) of the low pressure vertical furnace.

In this way the liner 2 may be made rather thin and of a relatively weak material since it doesn't have to compensate for atmospheric pressure. This creates a larger freedom in choosing the material for the liner 2. The thermal expansion of the material of liner 2 may be chosen such that it may be comparable with the material deposited on the substrate in the inner space. The latter having the advantage that the expansion of the liner and the material deposited also on the liner may be the same. The latter minimizes the risk of the deposited material (flakes) dropping of as a result of temperature changes of the liner 2.

The tube 12 may be made rather thick and of a relatively strong compressive strength material since it may have to compensate for atmospheric pressure with respect to the low pressure on the inside of the tube. For example, the low pressure process tube 12 can be made of 5 to 8, preferably around 6 mm thick quartz. Quartz has a very low Coefficient of Thermal Expansion (CTE) of 0.59×10-6 K⁻¹ (see table 1) which makes it more easy to cope with thermal fluctuations in the apparatus. Although the CTE of the deposited materials may be higher (e.g., CTE of Si₃N₄ is 3×10⁻⁶ K⁻¹, CTE of Si is 2.3×10⁻⁶ K⁻¹), the differences may be relatively small. When films are deposited onto the tube made of quartz, they may adhere even when the tube goes through many large thermal cycles however the risk of contamination may be increasing.

The liner 2 may circumvent any deposition on the inside of the tube 2 and therefore the risk of deposition on the tube 12 dropping off may be alleviated. The tube may therefore be made from quartz while the liner 2 may be made of silicon carbide (SiC). The CTE of SiC is 4×10⁻⁶ K⁻¹ and may provide a match in CTE with the deposited film, resulting in a greater cumulative thickness before removal of the deposited film from the liner may be required.

Mismatches in CTE result in cracking of the deposited film and flaking off, and correspondingly high particle counts, which is undesirable and may be alleviated by using a SIC liner 2. The same mechanism may work for the injector 17; however, for injectors 17, it may be the case that the injector may be breaking if too much material with different thermal expansion is deposited. It may therefore be advantageously to manufacture the injector 17 from silicon carbide or silicon.

TABLE 1
Coefficient of Thermal Expansion (CTE) of Materials
in Semiconductor Processing

| Material | Thermal expansion (ppm/K) |
|---|---|
| Quartz | 0.59 |
| Silicon nitride | 3 |
| Silicon | 2.3 |
| Silicon carbide | 4.0 |
| Tungsten | 4.5 |

Whether a material is suitable for the liner 2 and or the injector 17 may be dependent on the material that is deposited. It is therefore advantageously to be able to use material with substantially the same thermal expansion for the deposited material as for the liner 2 and/or the injector 17. It may therefore be advantageously to be able to use material with a thermal expansion for the liner 2 and/or the injector 17 relatively higher than that of quartz. For example, silicon carbide SiC may be used. The silicon carbide liner may be between 4 to 6, preferably 5 mm thick since it doesn't have to compensate for atmospheric pressure. Pressure compensation may be done with the tube.

For systems depositing metal and metal compound materials with a CTE between about 4×10⁻⁶ K⁻¹ and 6×10⁻⁶ K⁻¹, such as TaN, HfO₂ and TaO₅, the liner and injector materials preferably may have a CTE between about 4×10⁻⁶ K⁻¹ and 9×10⁻⁶ K⁻¹, including, e.g., silicon carbide.

For deposition of material with even a higher CTE, the liner and/or injector materials may be chosen as, for example, depicted by table 2.

TABLE 2
Coefficient of Thermal Expansion (CTE) of
Ceramic Construction Materials

| Material | Thermal expansion (ppm/K) |
|---|---|
| Macor | 12.6 |
| Boron Nitride | 11.9 |
| Glass, ordinary | 9 |
| Mullite | 5.4 |

The assembly may be provided with a purge gas inlet 19 mounted on the flange 3 for providing a purge gas P to the circumferential space S between an outer surface of the liner 2b and the process tube 12. The purge gas inlet may comprises a purge gas nozzle 20 extending vertically along the outer surface of the cylindrical wall of the liner 2 from the flange 3 towards the top end of the liner. The purge gas P to the circumferential space S may create a flow in the gas exhaust openings 8 and counteract diffusion of reaction gas from the exhaust tube 7 to the circumferential space S.

The flange 3 may have an upper surface. The liner 2 may be supported by support members 4 that may be connected to the outer cylindrical surface of the liner wall 2a and each have a downwardly directed supporting surface. The liner may also be supported directly on the upper surface of the flange 3 with it lower surface 2c.

The supporting surfaces of the support members 4 may be positioned radially outwardly from the inner cylindrical surface 2b of the liner 2. In this example, the supporting surfaces of the supporting members 4 may be also positioned radially outwardly from the outer cylindrical surface 2a of the liner 2 to which they are attached. The downwardly directed supporting surface of the support members 4 may be in contact with the upper surface of the flange 3 and support the liner 2.

The support flange 3 of the closure may include gas exhaust openings 8 to remove gas from the inner space of the liner 2 and the circular spaces between the liner 2 and the low pressure tube 12. At least some of the gas exhaust openings may be provided in the upper surface of the flange 3 radially outside of the liner 2. At least some of the gas exhaust openings may be provided near the liner opening. The gas exhaust openings 8 may be in fluid connection with a pump via exhaust duct 7 for withdrawing gas from the inner space and the circumferential space between the process tube 12 and the liner 2. Any particles, which may be created by friction between the support members 4 and the upper surface part of the support flange 3 may be drained along with the gas through the gas exhaust openings 8. In any case, the released particles will not be able to enter the process chamber around the substrates W.

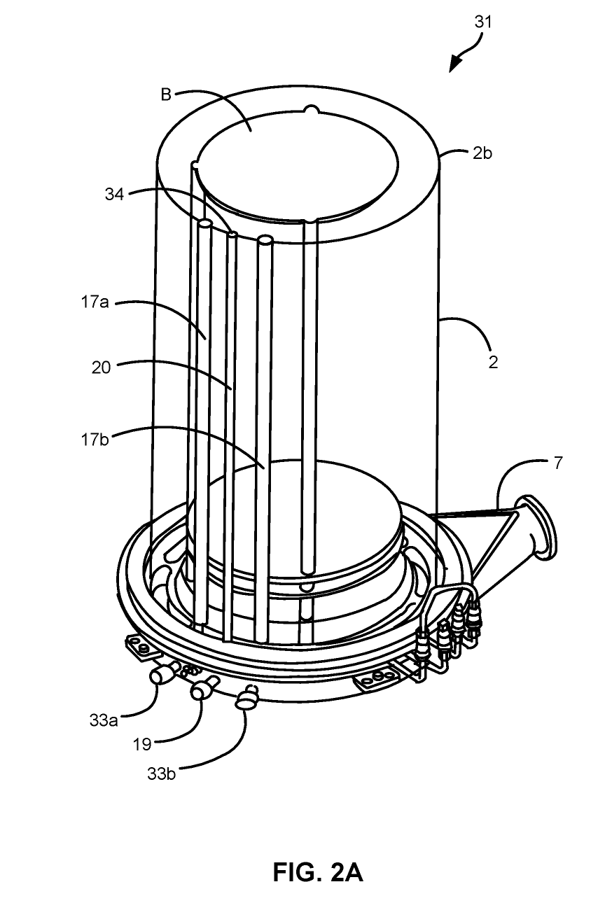

FIG. 2a illustrates a view on an assembly for use in a substrate processing apparatus according to an embodiment. FIG. 2a illustrates the assembly 31 comprising a liner 2 and injectors, 17a and 17b positioned on a flange 3. The injectors 17a and 17b each have a gas inlet 33a and 33b, respectively, for connecting to a gas injector system to provide the process gas to the interior of the reaction chamber. The liner 2 is an open liner with means that the liner is open at the top 2b which is different than the liner 2 in FIG. 1 which is closed at the top. A boat B for holding substrates may be located within the liner 2 for supporting substrates to be processed in the reaction chamber.

A purge gas nozzle 20 may be provided to purge an inert gas such as nitrogen gas in the reaction chamber from a purge gas inlet 19. The purge nozzle 20 has an opening at the top end 34 to allow purge gas to flow downward through the interior of the reaction chamber and to exit through the exhaust 7 in the flange. The purge nozzle 20 for the purge gas may preferably be a tube with an open end at the top and without gas discharge holes in its sidewall, so that all the purge gas is discharged at the top of the reaction chamber. The purge injector may be omitted and then purge gas may be supplied to one of the injectors 17 and 17b.

In other embodiments, the exhaust 7 can be at the top of the reaction chamber and the purge gas can be discharged at the bottom of the reaction chamber.

FIG. 2b illustrates a view on the gas injector system 35 constructed and arranged to provide the process gas to the interior of the reaction chamber of FIGS. 1, 2a. The gas injector system is provided with the first and second injector 17a, 17b and a gas control system 36 constructed and arranged to control the process gas flow from a source pipe 37 to the first and second injector 17a, 17b via the first and second gas inlet 33a, 33b respectively for the same process gas.

The gas control system 36 may be constructed and arranged to provide the flow of the process gas from the source pipe to one of the first and second injectors (e.g., the first injector 17a) while restricting a flow of the same process gas to another of the first and second injectors (e.g., the second injector 17b). The gas control system 36 may comprise a process gas valve 39 constructed and arranged to provide a flow of the process gas from the source pipe 37 to the first gas inlet 33a, while restricting a flow of the same process gas to the second gas inlet 33b in this example.

The second injector 17b may be provided with a continues purge gas flow from a purge gas source 41 via purge gas valve 43 and second gas inlet 33b to assure that no process gasses may flow into the interior of the second injector 17b to deposit there while it is not in use. The process gas valve 39 and the purge gas valve 43 may be controlled by controller 45 which may be programmed to control the valves 39, 43 to provide the flow of the process gas from the source pipe to one of the first and second injectors 17a, 17b, while restricting a flow of the same process gas to another of the first and second injectors 17a, 17b.

The flow of the process gas from the first to the second injector 17a, 17b may be switched by switching both the process gas valve 39 and the purge gas valve 43 under control of the controller 45—for example, after a predetermined time period or if the flow of process gas becomes lower than a certain threshold value. The control system 45 may be provided with a timer for switching after a predetermined time period. A flow of the process gas will then be directed from the source pipe 37 to the second gas inlet 33c, while restricting a flow of the same process gas to the first gas inlet 33a with the process gas valve 39. Optionally, the first injector 17a may be provided with a continues purge gas flow from a purge gas source 41 via purge gas valve 43 and first gas inlet 33a.

The flow of the process gas from the first to the second injector may be switched multiple times back and forth. The number of injectors in the injector system may be increased to three, four or even five to further increase the production period.

The gas control system may be provided with a gas flow measurement device to measure the flow of process gas and the gas control system may be constructed and/or programmed to switch the flow of process gas from the first to the second injector if the flow of process gas becomes lower than a certain threshold value. The flow of process gas from the first to the second injector may be switched if a particle count of flakes from the injector are becoming above a particle count threshold value.

The flow of process gas from the first to the second injector may be switched if the uniformity of the deposition on the substrates W in the reaction chamber is deteriorating or if, for example, the number of particles counted on the surface of the substrates W are increasing. The substrates may be provided to a measurement system outside or optional inside the apparatus to measure the uniformity or the number of particles on the substrate.

The first and second injectors may be replaced with fresh first and second injectors if both got clogged. For example, if the flow of process gas through the first and second injectors becomes lower than a second threshold value.

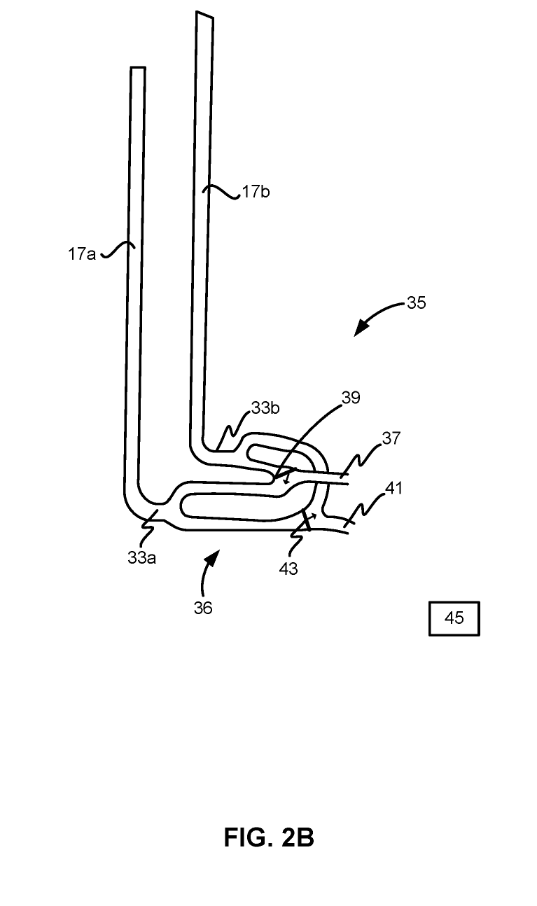

FIG. 3 depicts a perspective bottom view of an injector according to an embodiment located within the reaction chamber 12 of the apparatus according to FIG. 1 or 2a. Only one first injector 17 is shown with two injector branches 22, 23. Another, second injector may be located within the liner 2.

The injector 2 may also have three or four branches. One or more of the injectors may be multiple hole gas injectors. Advantageously, using multiple-hole gas injectors, the evenness of gas distribution into the reaction chamber 12 can be improved, thereby improving the uniformity of deposition results.

The injector 17 may be provided with a pattern of openings 26, the pattern extending substantially over the wafer load. According to the invention the total cross section of the openings is relatively large, for example, between 100 and 600, preferably between 200 and 400 mm². And the inner cross-section of the injector 17, available for the conduction of source gas, may be between 100 and 600, preferably 200 and 500 mm² or more. The inner cross section of the injector 17 may be helical shaped.

The opening diameter may be between 1 to 15 mm, preferably between 3 to 12 mm, more preferably between 4 and 10 mm. The area of the opening may be between 1 to 200 mm², preferably between 7 to 100 mm², more preferably between 13 and 80 mm². Larger openings may have the advantage that it takes longer for the openings to clog because of deposited layers within the openings.

In the example shown in FIG. 3, the injector as a whole may comprise 40 openings. For a diameter of 3 mm, the total cross-section of the openings may be 40×3×3×π/4=282 mm². The cross-section of each of the branches of the injector is about 11×30=330 mm². Other injectors may have 20 openings with a 4 mm diameter giving a total area of 251 mm². Other injectors may have 5 openings with a 8 mm diameter giving a total area of also 251 mm.

In each injector branch 22, 23, the openings may be provided pair-wise, at the same height, the two openings may inject the gas in two directions, under an angle of about 90 degrees, to improve the radial uniformity.

The openings may be positioned on the injector in a vertically and horizontally spaced apart relationship. The opening pattern on one injector branch may extend vertically with a higher concentration of openings at the higher part of the branch to compensate for a reducing gas flow in the higher part. The injector branches may be injector tubes, each injector tube with its feed end connected to a separate gas supply conduit. The injector tube may be connected via a separate gas supply conduit to a separate gas source for the separate injection of two or more source gases. The opening pattern on one injector branch may extend vertically over only a part of the boat. The injector 17 may be accommodated in bulge 2e in the liner 2.

The assembly may be provided with a temperature measurement system mounted on the flange and extending along an inner or outer surface of the cylindrical wall of the liner 2 towards the top end of the liner to measure a temperature. The temperature measurement system may comprise a beam with a plurality of temperature sensors provided along the length of the beam to measure the temperature at different heights along the liner.

A second bulge 2f may be provided in the liner 2 to accommodate the beam with the plurality of temperature sensors for measurement of the temperature inside the inner space if configured along an inner surface of the liner. As depicted the bulge is extending outwardly so as to accommodate the temperature measurement system on the inside of the liner however the bulge may also be extending inwardly to accommodate the temperature measurement system on the outside of the liner. By accommodating the injector and the temperature system in the bulges 2e and 2f respectively, the inner space can be kept substantially cylindrical symmetric, which is advantageous for the uniformity of a deposition process. The reaction chamber 12 may be provided at the bottom end with a broadening flange 27.

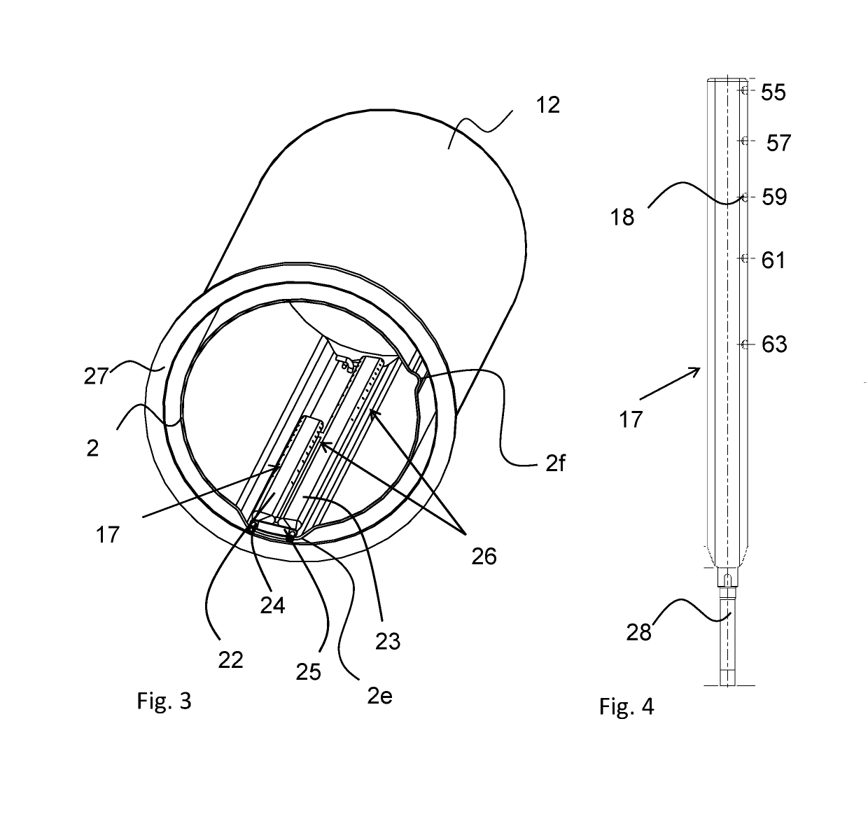

FIG. 4 depicts an injector 17 for use in the substrate processing apparatus of FIG. 1, 2a or 3. Five injector openings 18 are provided in the injector 17 numbered 55, 57, 59, 61, 63 from the top downward. The distance between the openings near the top of the injector 17 may be reduced compared to the distance at a lower end of the injector 17 to compensate for a reduced pressure at the top of the injector. The distance between the first and second openings 55, 57 may be between 45 and 49, preferably 47 mm, between openings 57 and 59 it may be between 50 and 56, preferably 53 mm, between openings 59 and 61 it may be between 55 and 59, preferably 57 mm, and between 61 and 63 it may be between 70 and 100, preferably 81 mm to compensate for the pressure reduction.

The total cross-section of the openings may be relatively large so that the pressure inside the injector is kept at a relatively low value. The diameter of the openings 18 may be between 4 and 15 mm. For example, the openings may have a diameter of 8 mm. Deposition within the openings of the injector may cause clogging of the injector openings. By having larger openings, e.g., 4 to 15 mm, preferably 8 mm it takes a longer time for the injector openings to clog up, which is increasing the lifetime of the injector.

The horizontal, inner cross-section of a gas conduction channel inside the injector may have an oblong shape with a dimension in a direction tangential to the circumference of the substantially cylindrical liner which is larger than a dimension in a radial direction. The lower part 28 of the injector 17 may have a smaller cross-section and accordingly a higher pressure. Normally, this may cause extra deposition, but since the temperature may be lower in this part, the deposition rate may still be acceptable.

The openings 18 of the gas injector 17 may be configured to reduce clogging of the openings. The openings may have a concave shape from the inside to the outside. The concave shape with the surface area of the opening on a surface on the inside of the injector larger than the surface area of the opening 18 on the outside of the injector may reduce clogging. The larger area on the inside allows more deposition at the inner side where the pressure and therefore the deposition is larger. On the outside the pressure is reduced and therefore the deposition is also slower and a smaller area may collect the same deposition as a larger diameter on the inside.

Reducing the pressure with the injector may result in a reduction of the reaction rate within the injector 17 because the reaction rate typically increases with increasing pressure. An additional advantage of a low pressure inside the injector is that gas volume through the injector expands at low pressure, and for a constant flow of source gas the residence time of the source gas inside the injector reduces correspondingly. Because of the combination of both, the decomposition of the source gases can be reduced, and thereby deposition within the injector may be reduced as well.

Deposition within the injector may cause tensile strength in the injector causing the injector to break when temperature is changing. Less deposition within the injector therefore prolongs the life time of the injector 17. The injector may be made from a material which has the coefficient of thermal expansion of the material deposited with the process gas. For example, the injector may be made from silicon nitride if silicon nitride is deposited or from silicon if silicon is deposited by the process gas. The thermal expansion of the deposited layer within the injector may therefore match the thermal expansion of the injector, decreasing the chance that the gas injector may break during changes of temperature. Silicon carbide may be a suitable material for the injector 17, because it has a thermal expansion which may match many deposited materials.

A disadvantage of a low pressure inside the injector is that the conduction of the injector decreases significantly. This would lead to a poor distribution of the flow of source gas over the opening pattern over the length of the injector: the majority of source gas will flow out of the holes near the inlet end of the injector. To facilitate the flow of source gas inside the injector, along the length direction of the injector, the injector may be provided with a large inner cross section. In order to be able to accommodate the injector according to the invention inside the reaction space, the tangential size of the injector may be larger than the radial size and the liner delimiting the reaction space may be provided with an outwardly extending bulge to accommodate the injector.

In the preferred embodiment, the two source gases, providing the two constituting elements of the binary film, are mixed in the gas supply system prior to entering the injector. This is the easiest way to ensure a homogeneous composition of the injected gas over the length of the boat. However, this is not essential. Alternatively, the two different source gases can be injected via separate injectors and mixed after injection in the reaction space.

The use of two injector branches allows some tuning possibilities. When gas of substantially the same composition is supplied to both parts of the injector, via separate source gas supply, the flows supplied to the different injector branches can be chosen different to fine-tune the uniformity in deposition rate over the boat. It is also possible to supply gas of different composition to the two lines of the injector to fine-tune the composition of the binary film over the boat. However, the best results may be achieved when the composition of the injected gas was the same for both injector lines.

While specific embodiments have been described above, it will be appreciated that the invention may be practiced otherwise than as described. The descriptions above are intended to be illustrative, not limiting. Thus, it will be apparent to one skilled in the art that modifications may be made to the invention as described in the foregoing, without departing from the scope of the claims set out below. Various embodiments may be applied in combination or may be applied independently from one another.

What is claimed is:

1. A substrate processing apparatus comprising:
a reaction chamber;
a substrate holder constructed and arranged to hold at least one substrate in said reaction chamber; and,
a gas injector system constructed and arranged to provide a process gas to the interior of the reaction chamber and provided with a gas control system constructed and arranged to control the process gas flow from a source pipe; wherein the gas injector system comprises a first and second injector for the same process gas and the gas control system is constructed, arranged, and/or programmed to provide the flow of the process gas from the source pipe to one of the first and second injectors while restricting a flow of the same process gas to another of the first and second injectors.

2. The substrate processing apparatus according to claim 1, wherein the gas control system is constructed, arranged and/or programmed to switch the flow of process gas from said one of the first and second injector to the other of the first and second injectors.

3. The substrate processing apparatus according to claim 2, wherein the gas control system is constructed, arranged and/or programmed to restrict the flow of the process gas from the source pipe to said one of the first and second injector after switching the flow of process gas from said one of the first and second injector to the other of the first and second injectors.

4. The substrate processing apparatus according to claim 2, wherein the gas control system is provided with a timer and is constructed and/or programmed to switch after a predetermined time period.

5. The substrate processing apparatus according to claim 2, wherein the gas control system is provided with a gas flow measurement device to measure the flow of process gas and the gas control system is constructed and/or programmed to switch if the flow of process gas becomes lower than a certain threshold value.

6. The substrate processing apparatus according to claim 1, wherein the apparatus comprises a liner constructed and arranged to extend in the interior of the reaction chamber along the walls of the reaction chamber.

7. The substrate processing apparatus according to claim 6, wherein the liner comprises a substantial cylindrical wall delimited by a liner opening at a lower end and a top closure at a higher end, the liner being substantially closed above the liner opening for gasses.

8. The substrate processing apparatus according to claim 7, wherein the first and second injectors are constructed and arranged along the substantially cylindrical wall of the liner towards the higher end.

9. The substrate processing apparatus according to claim 1, wherein the first and second injectors are elongated and are provided with a pattern of openings.

10. The substrate processing apparatus according to claim 9, wherein an inner cross-section area of a gas conduction channel inside the injector is between 100 and 1500 mm2.

11. The substrate processing apparatus according to claim 10, wherein the inner cross-section of the gas conduction channel inside the injector has a shape with a dimension in a direction tangential to the circumference of the substantially cylindrical reaction chamber which is larger than a dimension in a radial direction.

12. The substrate processing apparatus according to claim 9, wherein an area of at least one opening may be between 1 to 200 mm².

13. The substrate processing apparatus according to claim 9, wherein a distance between the openings decrease when going from a lower end to a top end of the injector.

14. The substrate processing apparatus according to claim 9, wherein the openings are configured such that gas is injected in at least two different directions.

15. A substrate processing method comprising:
providing a substrate on a substrate holder in a reaction chamber;
providing a flow of a process gas from a source pipe with a first gas injector into the interior of the reaction chamber; and,
restricting a flow of the same process gas from the source pipe to a second injector into the interior of the reaction chamber.

16. The substrate processing method according to claim 15, wherein the method comprises switching the flow of the process gas from the first to the second injector.

17. The substrate processing method according to claim 16, wherein the method comprises restricting the flow of the process gas from the source pipe to the first injector after switching the flow of process gas from the first to the second injector.

18. The substrate processing method according to claim 16, wherein the method comprises switching the flow of process gas from the first to the second injector after a predetermined time period.

19. The substrate processing method according to claim 16, wherein the method comprises switching the flow of process gas from the first to the second injector if the flow of process gas becomes lower than a certain threshold value, particles are detected or the uniformity of deposition on the wafer is not good.

20. The substrate processing method according to claim 17, wherein the method comprises replacing the first and second injectors with fresh first and second injectors.
